(19) United States
(12) Patent Application Publication
(10) Pub. No.: US 2024/0380173 A1
(43) Pub. Date: Nov. 14, 2024

(54) VERTICAL CAVITY LIGHT-EMITTING ELEMENT

(71) Applicants: MEIJO UNIVERSITY, Nagoya-shi, Aichi (JP); STANLEY ELECTRIC CO., LTD., Meguro-ku, Tokyo (JP)

(72) Inventors: Tetsuya TAKEUCHI, Aichi-shi, Nagoya (JP); Masaru KURAMOTO, Meguro-ku, Tokyo (JP)

(73) Assignees: MEIJO UNIVERSITY, Nagoya-shi, Aichi (JP); STANLEY ELECTRIC CO., LTD., Meguro-ku, Tokyo (JP)

(21) Appl. No.: 18/683,889

(22) PCT Filed: Aug. 4, 2022
(86) PCT No.: PCT/JP2022/029935

§ 371 Date: Feb. 15, 2024

(30) Foreign Application Priority Data
Aug. 20, 2021 (JP) 2021-135105

(51) Int. Cl. H01S 5/042; H01S 5/183

(52) U.S. Cl. CPC H01S 5/04256; H01S 5/18361

(57) ABSTRACT

A surface emitting laser includes a gallium-nitride-based semiconductor substrate, a first multilayer reflector, a semiconductor structure layer including an active layer, a first electrode layer, a second electrode layer formed on an upper surface of the semiconductor structure layer and electrically in contact with a semiconductor layer of the semiconductor structure layer in one region of the upper surface, and a second multilayer reflector configuring a resonator between the first multilayer reflector and the second multilayer reflector. An upper surface of the semiconductor substrate is a surface offset from a c-plane to any one of crystal planes of an m-plane—or an a-plane. The one region has a shape having a longitudinal direction in an m-axis direction when the upper surface is offset to the m-plane, and a shape having a longitudinal direction in an a-axis direction when the upper surface is offset to the a-plane.

### TECHNICAL FIELD

The present invention relates to a vertical cavity light-emitting element, such as a vertical cavity surface emitting laser (VCSEL).

### BACKGROUND ART

Conventionally, as one of the semiconductor lasers, there has been known a vertical cavity-type semiconductor surface emitting laser (hereinafter also simply referred to as a surface emitting laser) including a semiconductor layer that emits light by application of voltage and multilayer reflectors opposed to one another with the semiconductor layer interposed therebetween. For example, Patent Document 1 discloses a vertical cavity-type semiconductor laser having an n-electrode and a p-electrode connected to an n-type semiconductor layer and a p-type semiconductor layer, respectively.
Patent Document 1: JP-A-2017-98328

### DISCLOSURE OF THE INVENTION

### Problems to be Solved by the Invention

For example, in a vertical cavity light-emitting element, such as a surface emitting laser, an optical resonator is formed by opposing reflectors. For example, in the surface emitting laser, when a voltage is applied to a semiconductor layer through an electrode, light emitted from the semiconductor layer resonates in the optical resonator, generating laser light.

However, for example, a vertical cavity-type semiconductor laser element is low in luminous efficiency compared with a horizontal cavity-type semiconductor laser having a resonator in an in-plane direction of a semiconductor layer including an active layer, which is an example of a problem.

In addition, light emitted from a vertical cavity-type semiconductor laser element using a GaN-based substrate has often been elliptically polarized light or linearly polarized light with various polarization directions.

Moreover, it has been difficult to stabilize the polarization direction during operation, such as that the polarization direction has changed depending on changes in driving current and operating temperature.

The present invention has been made in consideration of the above-described points and it is an object to provide a vertical cavity light-emitting element that has high luminous efficiency and allows stably emitting light in a specific polarization direction.

### Solutions to the Problems

A vertical cavity light-emitting element according to the present invention includes a gallium-nitride-based semiconductor substrate, a first multilayer reflector, a semiconductor structure layer, a first electrode layer, a second electrode layer, and a second multilayer reflector. The first multilayer reflector is made of a nitride semiconductor formed on the substrate. The semiconductor structure layer includes a first semiconductor layer, an active layer, and a second semiconductor layer. The first semiconductor layer is made of a nitride semiconductor having a first conductivity type formed on the first multilayer reflector. The active layer is made of a nitride semiconductor formed on the first semiconductor layer. The second semiconductor layer is formed on the active layer and made of a nitride semiconductor having a second conductivity type opposite of the first conductivity type. The first electrode layer is electrically in contact with the first semiconductor layer of the semiconductor structure layer. The second electrode layer is formed on an upper surface of the semiconductor structure layer. The second electrode layer is electrically in contact with the second semiconductor layer of the semiconductor structure layer in one region of the upper surface. The second multilayer reflector is formed to cover the one region on the electrode layers. The second multilayer reflector configures a resonator between the first multilayer reflector and the second multilayer reflector. An upper surface of the gallium-nitride-based semiconductor substrate is a surface offset from a c-plane to any one of crystal planes of an M-plane or an A-plane. The one region has a shape having a longitudinal direction in an m-axis direction when the upper surface is offset to the M-plane, and a shape having a longitudinal direction in an a-axis direction when the upper surface is offset to the A-plane.

### BRIEF DESCRIPTION OF THE DRAWINGS

FIG. 1 is a perspective view of a surface emitting laser of Embodiment 1.

FIG. 2 is a top view of the surface emitting laser of Embodiment 1.

FIG. 3 is a cross-sectional view of the surface emitting laser of Embodiment 1.

FIG. 4 is a bottom view of a surface emitting laser of Embodiment 2.

FIG. 5 is a cross-sectional view of the surface emitting laser of Embodiment 2.

FIG. 6 is a bottom view of a surface emitting laser of Embodiment 3.

FIG. 7 is a cross-sectional view of the surface emitting laser of Embodiment 3.

FIG. 8 is a top view of a surface emitting laser of a modification.

FIG. 9 is a top view of a surface emitting laser of a modification.

FIG. 10 is a top view of a surface emitting laser of a modification.

FIG. 11 is a top view of a surface emitting laser of a modification.

FIG. 12 is a top view of a surface emitting laser of a modification.

### DESCRIPTION OF PREFERRED EMBODIMENTS

The following describes embodiments of the present invention in detail. While in the following description, a description will be made using a semiconductor surface emitting laser element as an example, the present invention is applicable, not only to a surface emitting laser, but also to various kinds of vertical cavity light-emitting elements, such as a vertical cavity-type light-emitting diode.

### Embodiment 1

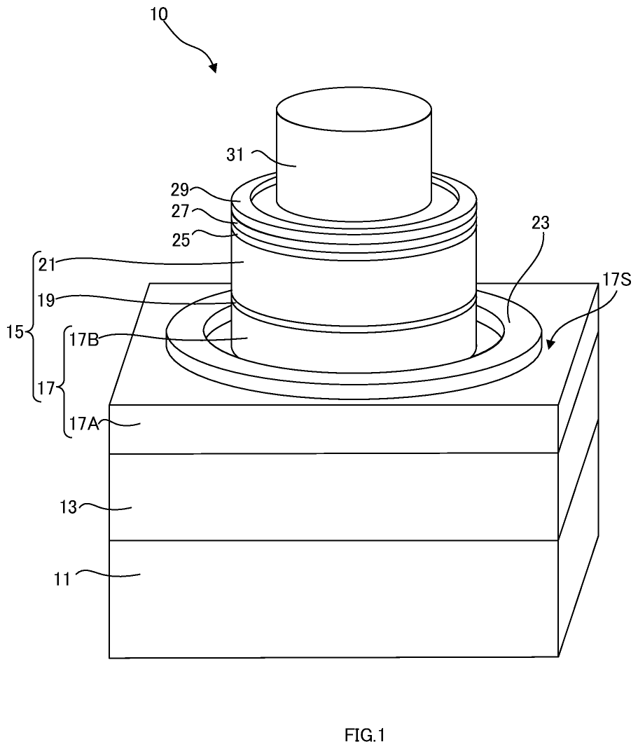

FIG. 1 is a perspective view of a vertical cavity surface emitting laser (VCSEL, hereinafter also simply referred to as a surface emitting laser) 10 according to Embodiment 1.

A substrate 11 is a gallium-nitride-based semiconductor substrate, for example, a GaN substrate. The substrate 11 is, for example, a substrate with a rectangular upper surface shape. The substrate 11 is a coreless substrate manufactured such that dislocations are uniformly distributed all over and a core, which is an aggregate of dislocation defects, is not formed.

An upper surface of the substrate 11 is a surface offset by 0.5° in a direction from a C-plane to an M-plane. In addition, the upper surface of the substrate 11 is hardly offset in a direction from the C-plane to an A-plane, and an offset angle in the direction from the C-plane to the A-plane is 0±0.1°.

A first multilayer reflector 13 is a semiconductor multilayer reflector made of a semiconductor layer that has been grown on the substrate 11. The first multilayer reflector 13 is formed by alternately laminating a low refractive-index semiconductor film having a composition of AlInN and a high refractive-index semiconductor film having a GaN composition and having a refractive index higher than that of the low refractive-index semiconductor film. In other words, the first multilayer reflector 13 is a distributed Bragg reflector (DBR) made of a semiconductor material.

For example, the first multilayer reflector 13 is formed by disposing a buffer layer having a GaN composition on the upper surface of the substrate 11 and alternately depositing films of the high refractive-index semiconductor film and the low refractive-index semiconductor film described above on the buffer layer.

A semiconductor structure layer 15 is a laminated structure made of a plurality of semiconductor layers formed on the first multilayer reflector 13. The semiconductor structure layer 15 has an n-type semiconductor layer (a first semiconductor layer) 17 formed on the first multilayer reflector 13, a light-emitting layer (or an active layer) 19 formed on the n-type semiconductor layer 17, and a p-type semiconductor layer (a second semiconductor layer) 21 formed on the active layer 19.

The n-type semiconductor layer 17 as a first conductivity type semiconductor layer is a semiconductor layer formed on the first multilayer reflector 13. The n-type semiconductor layer 17 is a semiconductor layer that has a GaN composition and is doped with Si as n-type impurities. The n-type semiconductor layer 17 has a prismatic-shaped lower portion 17A and a column-shaped upper portion 17B disposed on the lower portion 17A. Specifically, for example, the n-type semiconductor layer 17 has the column-shaped upper portion 17B projecting from an upper surface 17S of the prismatic-shaped lower portion 17A. In other words, the n-type semiconductor layer 17 has a mesa-shaped structure including the upper portion 17B.

The active layer 19 is a layer that is formed on the upper portion 17B of the n-type semiconductor layer 17 and has a quantum well structure including a well layer having an InGaN composition and a barrier layer having a GaN composition. In the surface emitting laser 10, light is generated in the active layer 19.

The p-type semiconductor layer 21 as a second conductivity type semiconductor layer is a semiconductor layer having a GaN composition formed on the active layer 19. The p-type semiconductor layer 21 is doped with Mg as p-type impurities.

An n-electrode 23 is a metal electrode disposed on the upper surface 17S of the lower portion 17A of the n-type semiconductor layer 17 and electrically connected to the n-type semiconductor layer 17. The n-electrode 23 is formed into a ring shape so as to surround the upper portion 17B of the n-type semiconductor layer 17. The n-electrode 23 is electrically in contact with the n-type semiconductor layer 17 and forms a first electrode layer that supplies a current from an outside to the semiconductor structure layer 15.

An insulating layer 25 is a layer made of an insulator formed on the p-type semiconductor layer 21. The insulating layer 25 is formed of a substance having a refractive index lower than that of a material forming the p-type semiconductor layer 21, such as SiO₂. The insulating layer 25 is formed into a ring shape on the p-type semiconductor layer 21 and is provided with an opening (not illustrated) that exposes the p-type semiconductor layer 21 at a central portion.

A transparent electrode 27 is a metal oxide film having translucency formed on an upper surface of the insulating layer 25. The transparent electrode 27 covers the entire upper surface of the insulating layer 25 and an entire upper surface of the p-type semiconductor layer 21 exposed from the opening formed in the central portion of the insulating layer 25. As the metal oxide film forming the transparent electrode 27, for example, ITO or IZO having translucency relative to emitted light from the active layer 19 can be used.

A p-electrode 29 is a metal electrode formed on the transparent electrode 27. The p-electrode 29 is electrically connected to the upper surface of the p-type semiconductor layer 21 exposed from the above-described opening of the insulating layer 25 via the transparent electrode 27. The transparent electrode 27 and the p-electrode 29 forms a second electrode layer that is electrically in contact with the p-type semiconductor layer 21 and supplies a current from the outside to the semiconductor structure layer 15. In this embodiment, the p-electrode 29 is formed on an upper surface of the transparent electrode 27 in a ring shape along an outer edge of the upper surface.

A second multilayer reflector 31 is a column-shaped multilayer reflector formed in a region surrounded by the p-electrode 29 on the upper surface of the transparent electrode 27. The second multilayer reflector 31 is a dielectric multilayer reflector in which a low refractive-index dielectric film made of Al₂O₃ and a high refractive-index dielectric film made of Ta₂O₅ and having a refractive index higher than that of the low refractive-index dielectric film are alternately laminated. In other words, the second multilayer reflector 31 is a distributed Bragg reflector (DBR) made of a dielectric material.

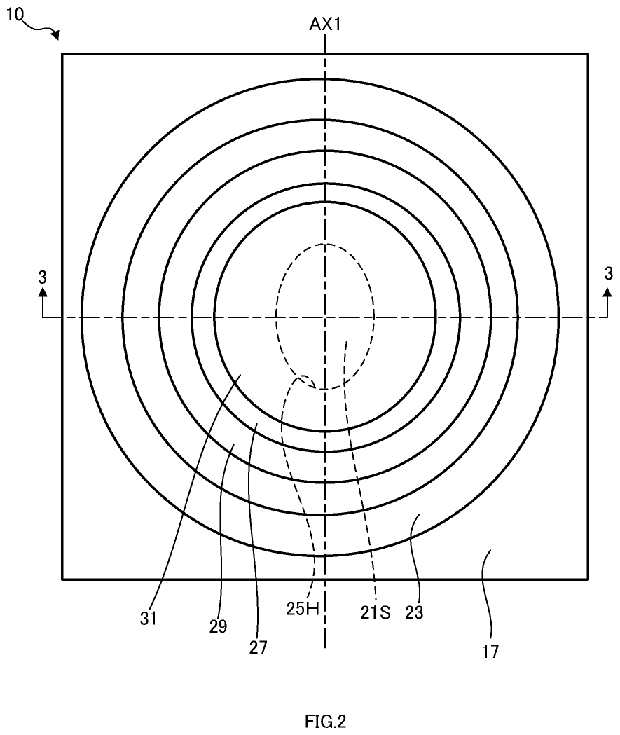

FIG. 2 is a top view of the surface emitting laser 10. As described above, the surface emitting laser 10 has the n-type semiconductor layer 17 formed on the substrate 11 having a rectangular upper surface shape and the semiconductor structure layer 15 including the active layer 19 with an elliptical upper surface shape and the p-type semiconductor layer 21 (see FIG. 1). The insulating layer 25 and the transparent electrode 27 are formed on the p-type semiconductor layer 21. The p-electrode 29 and the second multilayer reflector 31 are formed on the transparent electrode 27. Note that in FIG. 2, a direction along an axis AX1 is an m-axis direction of the substrate 11.

The insulating layer 25 has an opening 25H which is the above-described elliptical opening of the insulating layer 25 that exposes the p-type semiconductor layer 21. As illustrated in FIG. 2, the opening 25H is formed at the center of the insulating layer 25 when viewed from an upper side of the surface emitting laser 10 and is covered with the second multilayer reflector 31 when viewed from the upper side of the surface emitting laser 10. In other words, the opening 25H is formed in a region of the insulating layer 25 opposed to a lower surface of the second multilayer reflector 31.

The opening 25H has an elliptical shape having a long axis in the direction along the axis AX1. Therefore, the p-type semiconductor layer 21 is electrically connected to the transparent electrode 27 via an electrical contact surface 21S that lies in an elliptical region on the upper surface of the p-type semiconductor layer 21, is exposed from the opening 25H, and has a long axis in the m-axis direction. In other words, the opening 25H and the electrical contact surface 21S, the outline of which is defined by the opening 25H, have a shape having a longitudinal direction in the m-axis direction.

Furthermore, in the top view, that is, when viewed in a normal direction perpendicular to the upper surface of the substrate 11, of straight lines passing through the center of the electrical contact surface 21S on the upper surface of the p-type semiconductor layer 21, an extending direction of a straight line whose portion passing across the electrical contact surface 21S is the longest matches the m-axis direction.

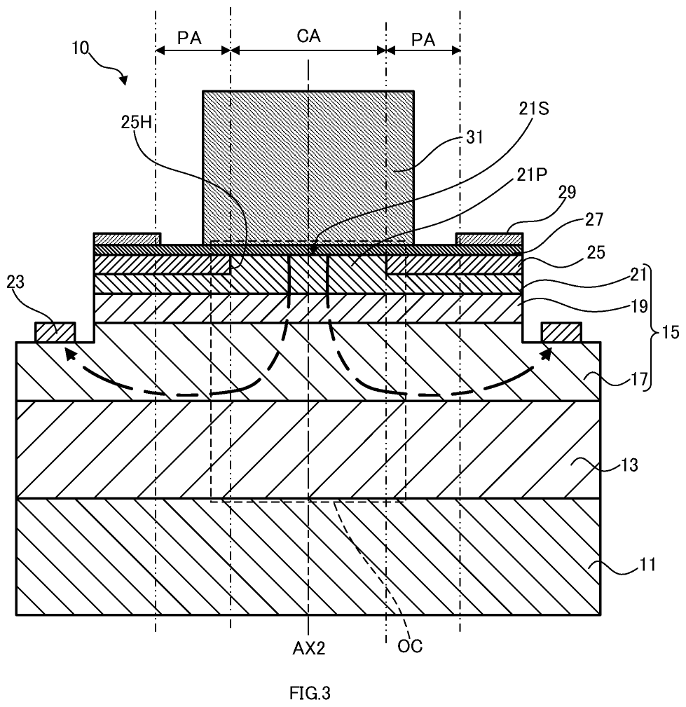

FIG. 3 is a cross-sectional view of the surface emitting laser 10 taken along the line 3-3 in FIG. 2. As described above, the surface emitting laser 10 has the substrate 11 as the GaN substrate, and the first multilayer reflector 13 is formed on the substrate 11. Note that a lower surface of the substrate 11 may be applied with an AR coating.

The semiconductor structure layer 15 is formed on the first multilayer reflector 13. The semiconductor structure layer 15 is a laminated body made by forming the n-type semiconductor layer 17, the active layer 19, and the p-type semiconductor layer 21 in this order. At the center on the upper surface of the p-type semiconductor layer 21, a projecting portion 21P projecting upward is formed.

The insulating layer 25 is formed to cover a region of the upper surface of the p-type semiconductor layer 21 other than the projecting portion 21P. The insulating layer 25 is made of a material having a refractive index lower than that of the p-type semiconductor layer 21 as described above. The insulating layer 25 has the opening 25H that exposes the projecting portion 21P. For example, as illustrated in FIG. 2, the opening 25H is in an elliptical shape. For example, the opening 25H and the projecting portion 21P have similar shapes, and an inner surface of the opening 25H is in contact with an outer surface of the projecting portion 21P. In other words, the projecting portion 21P also has an elliptical upper surface shape.

The transparent electrode 27 is formed to cover upper surfaces of the insulating layer 25 and the projecting portion 21P exposed from the opening 25H of the insulating layer 25. That is, the transparent electrode 27 is electrically in contact with the p-type semiconductor layer 21 in a region exposed by the opening 25H on the upper surface of the p-type semiconductor layer 21. In other words, the region exposed through the opening 25H on the upper surface of the p-type semiconductor layer 21 is the electrical contact surface 21S, which yields an electrical contact between the p-type semiconductor layer 21 and the transparent electrode 27.

The p-electrode 29 is a metal electrode as described above and formed along the outer edge of the upper surface of the transparent electrode 27. That is, the p-electrode 29 is electrically in contact with the transparent electrode 27. Accordingly, the p-electrode 29 is electrically in contact with or connected to the p-type semiconductor layer 21 via the transparent electrode 27 on the electrical contact surface 21S exposed by the opening 25H on the upper surface of the p-type semiconductor layer 21.

The second multilayer reflector 31 is formed on the upper surface of the transparent electrode 27 and in a region on the opening 25H of the insulating layer 25, in other words, a region on the electrical contact surface 21S, that is, at the central portion of the upper surface of the transparent electrode 27. The lower surface of the second multilayer reflector 31 is opposed to the upper surface of the first multilayer reflector 13 with the transparent electrode 27 and the semiconductor structure layer 15 interposed therebetween. The arrangement of the first multilayer reflector 13 and the second multilayer reflector 31 forms a resonator that resonates light emitted from the active layer 19 with the first multilayer reflector 13 and the second multilayer reflector 31.

In the surface emitting laser 10, the first multilayer reflector 13 has reflectivity slightly lower than that of the second multilayer reflector 31. Accordingly, a part of the light resonated between the first multilayer reflector 13 and the second multilayer reflector 31 transmits through the first multilayer reflector 13 and the substrate 11 to be taken out to the outside.

Here, an operation of the surface emitting laser 10 will be described. In the surface emitting laser 10, when a voltage is applied between the n-electrode 23 and the p-electrode 29, a current flows in the semiconductor structure layer 15 as indicated by the one-dot chain bold line in the drawing, and light is emitted from the active layer 19. The light emitted from the active layer 19 is repeatedly reflected between the first multilayer reflector 13 and the second multilayer reflector 31 to become a resonant state (that is, to laser oscillate).

In the surface emitting laser 10, the current is injected to the p-type semiconductor layer 21 only from a portion exposed by the opening 25H, that is, the electrical contact surface 21S. Since the p-type semiconductor layer 21 is considerably thin, the current does not spread in the in-plane direction, that is, in a direction along a surface of the semiconductor structure layer 15 in the p-type semiconductor layer 21.

Accordingly, in the surface emitting laser 10, the current is supplied only to a region immediately below the electrical contact surface 21S defined by the opening 25H in the active layer 19 and the light is emitted only from this region. That is, in the surface emitting laser 10, the opening 25H has a current confinement structure that restricts a supply range of the current in the active layer 19. In other words, in the surface emitting laser 10, the current confinement structure is formed which confines the current so that the current flows only to a central region CA, which is a columnar region with the electrical contact surface 21S as a bottom surface in the active layer 19. In other words, the central region CA including the region through which the current flows in the active layer 19 is defined by the electrical contact surface 21S.

As described above, in this embodiment, the first multilayer reflector 13 has reflectivity slightly lower than that of the second multilayer reflector 31. Accordingly, a part of the light resonated between the first multilayer reflector 13 and the second multilayer reflector 31 transmits through the first multilayer reflector 13 and the substrate 11 to be taken out to the outside. Thus, the surface emitting laser 10 emits the light in the direction perpendicular to the lower surface of the substrate 11 and the in-plane directions of the respective layers of the semiconductor structure layer 15 from the lower surface of the substrate 11. In other words, the lower surface of the substrate 11 is a light-emitting surface of the surface emitting laser 10.

Note that the electrical contact surface 21S of the p-type semiconductor layer 21 of the semiconductor structure layer 15 and the opening 25H of the insulating layer 25 define a luminescence center as the center of a light emission region in the active layer 19 and define a center axis (a luminescence center axis) AX2 of a resonator OC. The center axis AX2 of the resonator OC passes through the center of the electrical contact surface 21S of the p-type semiconductor layer 21 and extends along the direction perpendicular to the in-plane direction of the semiconductor structure layer 15.

Note that the light emission region of the active layer 19 is, for example, a region having a predetermined width through which light having a predetermined intensity or more is emitted in the active layer 19, and its center is the luminescence center. For example, the light emission region of the active layer 19 is a region to which a current having a predetermined density or more is injected in the active layer 19, and its center is the luminescence center. A straight line perpendicular to the upper surface of the substrate 11 or the in-plane directions of the respective layers of the semiconductor structure layer 15 passing through the luminescence center is the center axis AX2. The luminescence center axis AX2 is a straight line that extends along a resonator length direction of the resonator OC constituted of the first multilayer reflector 13 and the second multilayer reflector 31. The center axis AX2 corresponds to an optical axis of laser light emitted from the surface emitting laser 10.

Here, an exemplary configuration of the respective layers of the first multilayer reflector 13, the semiconductor structure layer 15, and the second multilayer reflector 31 in the surface emitting laser 10 will be described. In this embodiment, the first multilayer reflector 13 is made of a GaN base layer of 1 μm thickness and 42 pairs of n-GaN layers and AlInN layers formed on the upper surface of the substrate 11.

The n-type semiconductor layer 17 is an n-GaN layer having a layer thickness of 1580 nm. The active layer 19 is made of an active layer in a multiple quantum well structure in which four pairs of GaInN layers of 4 nm and GaN layers of 5 nm are laminated. On the active layer 19, an electronic barrier layer of AlGaN doped with Mg is formed and the p-type semiconductor layer 21 made of p-GaN layer of 50 nm is formed on the electronic barrier layer. The second multilayer reflector 31 is a lamination of 10.5 pairs of Nb₂O₅ and SiO₂. The resonant wavelength in this case was 440 nm.

The insulating layer 25 is a layer made of SiO₂ of 20 nm. In other words, the projecting portion 21P on the upper surface of the p-type semiconductor layer 21 projects 20 nm from the peripheral area. That is, the p-type semiconductor layer 21 has a layer thickness of 50 nm at the projecting portion 21P and a layer thickness of 30 nm in the region other than the projecting portion 21P. In addition, the upper surface of the insulating layer 25 is configured to be located at the same height position as the upper surface of the projecting portion 21P of the p-type semiconductor layer 21. Note that their configuration is merely an example.

The following describes optical features of an inside of the surface emitting laser 10. As described above, in the surface emitting laser 10, the insulating layer 25 has a refractive index lower than that of the p-type semiconductor layer 21. Layer thicknesses of the active layer 19 and the n-type semiconductor layer 17 between the first multilayer reflector 13 and the second multilayer reflector 31 are the same at any positions in plane insofar as in the same layer.

Accordingly, an equivalent refractive index (an optical distance between the first multilayer reflector 13 and the second multilayer reflector 31, which corresponds to a resonant wavelength) in the resonator OC formed between the first multilayer reflector 13 and the second multilayer reflector 31 of the surface emitting laser 10 differs in the central region CA and in a peripheral region PA in a pipe shape around the central region CA by a difference in refractive index between the p-type semiconductor layer 21 and the insulating layer 25. The central region CA is in an elliptical column shape with the electrical contact surface 21S in an elliptical shape having the long axis in a direction along the m-axis as a bottom surface.

Specifically, the equivalent refractive index in the peripheral region PA is lower than the equivalent refractive index in the central region, that is, an equivalent resonant wavelength in the central region CA is smaller than an equivalent resonant wavelength in the peripheral region PA between the first multilayer reflector 13 and the second multilayer reflector 31. Note that, as described above, somewhere the light is emitted in the active layer 19 is the region immediately below the opening 25H and the electrical contact surface 21S. That is, the light emission region where the light is emitted in the active layer 19 is a portion overlapping with the central region CA in the active layer 19, in other words, a region overlapping with the electrical contact surface 21S in the top view.

Thus, in the surface emitting laser 10, the central region CA including the light emission region of the active layer 19 and the peripheral region PA that surrounds the central region CA and has the refractive index lower than that of the central region CA are formed. This reduces an optical loss caused by diffusion (radiation) of a standing wave within the central region CA into the peripheral region PA. That is, a large quantity of light remains in the central region CA and laser light is taken out to the outside in this state. Accordingly, the large quantity of light concentrates in the central region CA in the peripheral area of the luminescence center axis AX2 of the resonator OC to ensure generating and emitting laser light with high output power and high density.

As described above, in the surface emitting laser 10 of this embodiment, the upper surface of the substrate 11 is a surface offset by 0.5° in the direction from the C-plane to the M-plane. As with the surface emitting laser 10 of this embodiment, when a semiconductor layer is grown on a growth surface offset to the M-plane of the substrate 11, an optical gain of light having a polarization direction in the m-axis direction is larger than that of light having a polarization direction in another direction. Accordingly, laser light having a polarization direction in the m-axis direction easily oscillates. Therefore, the light emitted from the central region CA of the surface emitting laser 10 is mostly light having a polarization direction in the m-axis direction.

In the surface emitting laser 10 of this embodiment, the upper surface shape of the electrical contact surface 21S is an elliptical shape having the long axis along the m-axis. That is, the shape of the electrical contact surface 21S has a longitudinal direction in a direction along the m-axis. This makes the central region CA an elliptical column shape with an ellipse having a long axis in the direction along the m-axis as a bottom surface. In other words, in the surface emitting laser 10 of this embodiment, the shape of the central region CA is an asymmetrical shape in which a diameter of the central region CA is different in the m-axis direction and in directions of other axes. In addition, the diameter of the central region CA becomes the largest in the m-axis direction.

The inventor of the present invention has found that, in the surface emitting laser 10, when the electrical contact surface 21S is in an elliptical shape having a long axis in the m-axis direction, that is, when the central region CA is in an elliptical column shape having an elliptical bottom surface having a long axis in the m-axis direction as described above, the reflectivity of the light having a polarization direction along the m-axis direction in the central region CA increases, an optical gain of the light having a polarization direction along the m-axis direction increases, and a loss in the m-axis direction decreases.

Accordingly, with the surface emitting laser 10, a large quantity of light having a polarization direction along the m-axis direction can be taken out from the lower surface of the substrate 11, which is the light-emitting surface of the surface emitting laser 10, and the emission of the light having a polarization direction other than the direction along the m-axis can be reduced. Therefore, with the surface emitting laser 10, a variation in the polarization direction of the light taken out from the light-emitting surface in the in-plane direction of the light-emitting surface can be reduced.

When the polarization direction of the emitted light was confirmed by actually driving the surface emitting laser 10 of Embodiment 1, it was confirmed that when the surface emitting laser 10 was driven at a driving current of 3 mA to 13 mA, the emitted light dominated by a light having a polarization direction in the m-axis direction is stably obtained under the condition of a device temperature of 20° C. to 80° C.

In addition, it has been confirmed that even if the long axis of the electrical contact surface 21S is tilted by about +5° with respect to the m-axis direction in the top view, the gain improvement effect of the light having a polarization direction along the m-axis direction described above can be sufficiently obtained.

As described above, with the surface emitting laser of the present invention, it is possible to have high luminous efficiency and stably obtain emitted light in a specific polarization direction. This is very effective when the emitted light of the surface emitting laser is used in a device having an optical system using a liquid crystal or polarizer.

### [Manufacturing Method]

The following describes an example of the method for manufacturing the surface emitting laser 10. First, an n-GaN substrate offset by 0.5° in the direction from the c-plane to the M-plane is prepared as the substrate 11, and on the substrate, an n-GaN layer (layer thickness 1 μm) is formed as a base layer using metalorganic vapor-phase epitaxy (MOVPE). Then, 42 pairs of n-GaN/AlInN layers are deposited on the base layer to form the first multilayer reflector 13.

Next, Si-doped n-GaN (layer thickness 1580 nm) is formed on the first multilayer reflector 13 to form the n-type semiconductor layer 17, and four pairs of layers made of GaInN (layer thickness 4 nm) and GaN (layer thickness 5 nm) are laminated on top of the n-type semiconductor layer 17 to form the active layer 19.

Next, an electronic barrier layer made of Mg-doped AlGaN is deposited on the active layer 19 (not illustrated), and a p-GaN layer (layer thickness 50 nm) is formed on the electronic barrier layer to form the p-type semiconductor layer 21.

Next, peripheral portions of the p-type semiconductor layer 21, the active layer 19, and the n-type semiconductor layer 17 are etched to form a mesa shape so that the upper surface 17S of the n-type semiconductor layer 17 is exposed in peripheral portions. In other words, in this step, the semiconductor structure layer 15 having a portion in an elliptical column shape including the n-type semiconductor layer 17, the active layer 19, and the p-type semiconductor layer 21 in FIG. 1 is completed.

Next, a peripheral area of the center of the upper surface of the p-type semiconductor layer 21 is etched to form the projecting portion 21P. Then, SiO₂ is deposited on the semiconductor structure layer 15, and by removing a part thereof to form the opening 25H, the insulating layer 25 is formed. In other words, SiO₂ is embedded in an etched and removed portion of the upper surface of the p-type semiconductor layer 21.

Next, 20 nm of ITO is deposited on the insulating layer 25 to form the transparent electrode 27, and Au is deposited on the transparent electrode 27 and the upper surface 17S of the n-type semiconductor layer 17 to form the p-electrode 29 and the n-electrode 23, respectively.

Next, 40 nm of Nb₂O₅ is deposited on the transparent electrode 27 as a spacer layer (not illustrated), and 10.5 pairs of layers, a pair of which is made of Nb₂O₅/SiO₂, are deposited on the spacer layer to form the second multilayer reflector 31.

Next, a back surface of the substrate 11 is polished, and an AR coat made of Nb₂O₅/SiO₂ is formed on the polished surface to complete the surface emitting laser 10.

### Embodiment 2

The following describes a surface emitting laser 40 as Embodiment 2 of the present invention. The surface emitting laser 40 is different from the surface emitting laser 10 in that slit grooves 41 are formed on the lower surface of the substrate 11, that is, the light-emitting surface of the surface emitting laser 40.

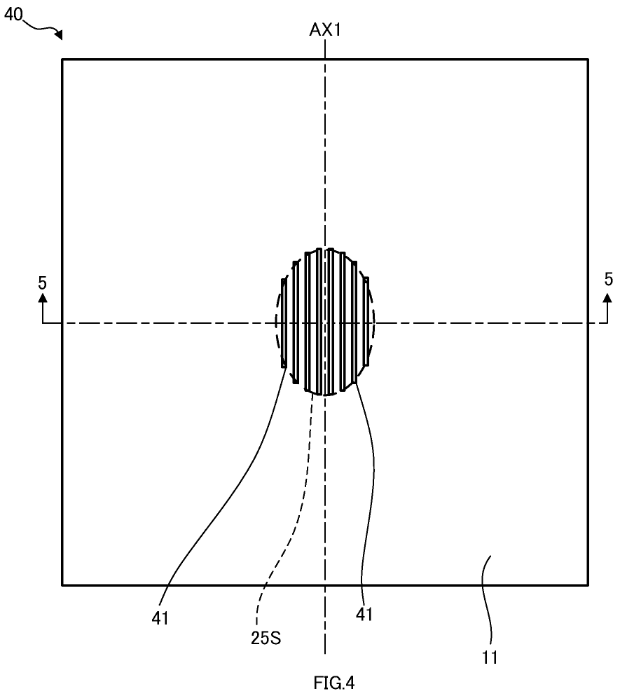

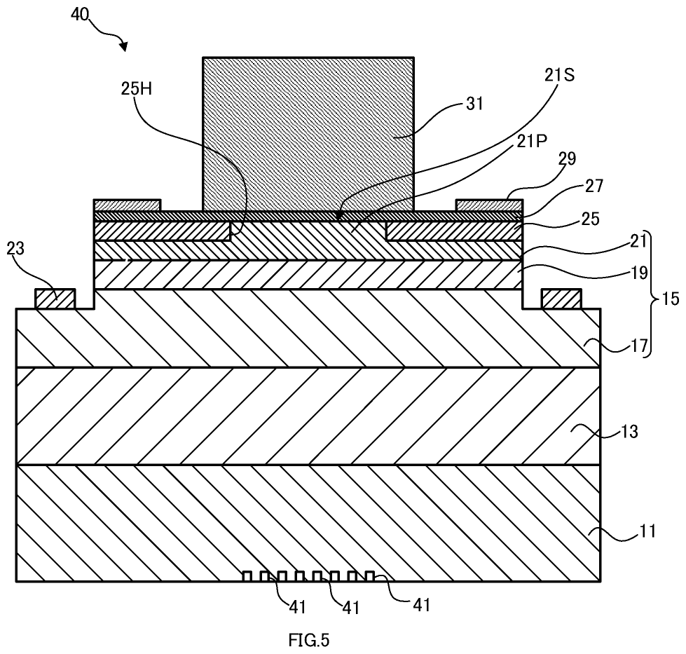

FIG. 4 illustrates a bottom view of the surface emitting laser 40 of Embodiment 2. FIG. 5 illustrates a cross-sectional view of the surface emitting laser 40 cut along the line 5-5 as a cut line similar to the one illustrated in FIG. 2 of the above-described Embodiment 1. As illustrated in FIG. 4 and FIG. 5, in the surface emitting laser 40, a plurality of slit grooves 41 are formed in a region on the lower surface of the substrate 11 opposed to the opening 25H and the electrical contact surface 21S, that is, a region where emitted light is emitted.

Each of the slit grooves 41 is a groove that extends parallel to the axis AX1 on the lower surface of the substrate 11 and is arranged in a direction perpendicular to the axis AX1, that is, a slit-shaped recessed portion. That is, the slit groove 41 is a groove extending along the m-axis direction on the lower surface of the substrate 11.

A diffraction grating formed by the slit grooves 41 yields high reflectivity to light having a polarization direction in an extending direction of the respective slit grooves 41 forming the diffraction grating, that is, the m-axis direction, in the central region CA of a reflection structure formed by the first multilayer reflector 13 and the substrate 11. That is, the slit grooves 41 are formed, thereby increasing the reflectivity of the light having a polarization direction in the m-axis direction than light having other polarization directions and making it easier for the light having a polarization direction in the m-axis direction to oscillate preferentially.

Therefore, with the surface emitting laser 40, by forming the diffraction grating structure including the slit grooves 41 on the lower surface of the substrate 11, further polarization control of the emitted light can be performed, and the light having one polarization direction can stably obtain dominant emitted light.

Note that the slit grooves 41 can be formed by performing, for example, an etching process, such as dry etching, on the lower surface of the substrate 11 after polishing the lower surface of the substrate 11 in the last step of the manufacturing process of the surface emitting laser 10 of Embodiment 1 described above.

In FIG. 4, while the slit grooves 41 are formed only in the region opposed to the opening 25H, the slit grooves 41 may extend further outward without limiting only in the region opposed to the opening 25H.

### Embodiment 3

The following describes a surface emitting laser 50 as Embodiment 3 of the present invention. The surface emitting laser 50 is different from the surface emitting laser 40 in that a convex portion is formed on the lower surface of the substrate 11, that is, the light-emitting surface of the surface emitting laser 50, and the slit grooves 41 described in Embodiment 2 are formed on a surface of the convex lens structure.

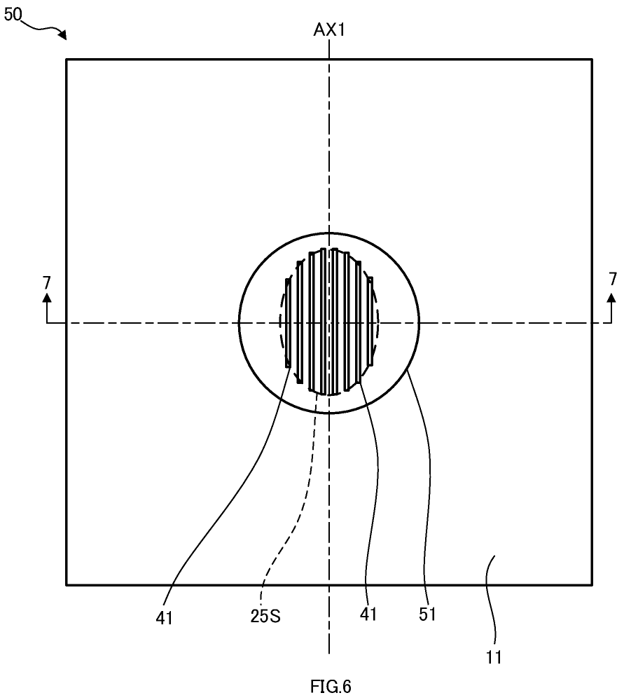

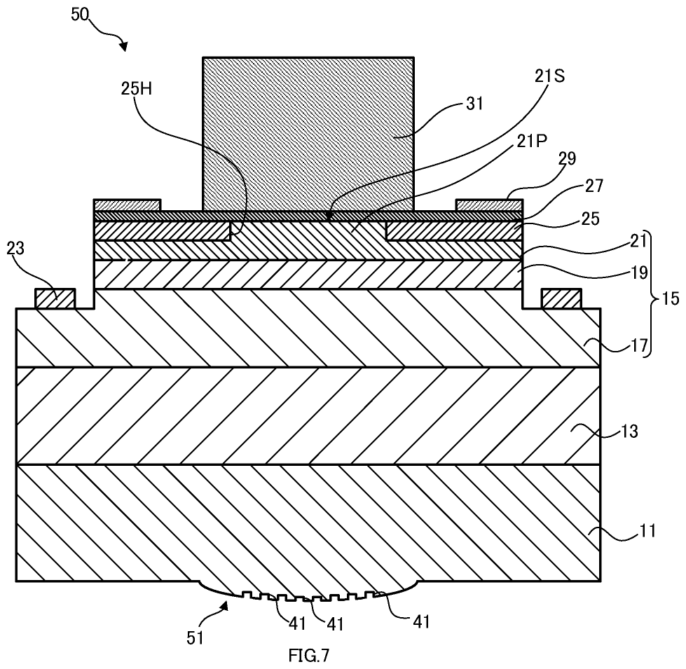

FIG. 6 illustrates a bottom view of the surface emitting laser 50 of Embodiment 3. FIG. 7 illustrates a cross-sectional view of the surface emitting laser 50 cut along the line 7-7 as a cut line similar to the one illustrated in FIG. 2 of the above-described Embodiment 1. As illustrated in FIG. 6 and FIG. 7, in the surface emitting laser 50, a convex portion 51 in a convex lens shape projecting downward is formed in a region including the region on the lower surface of the substrate 11 opposed to the opening 25H and the electrical contact surface 21S.

The convex portion 51 has a convex lens shape with the center axis AX2 described in Embodiment 1 as an apex. The plurality of slit grooves 41 are formed on the surface of the convex portion 51.

With the surface emitting laser 50 of Embodiment 3, the convex portion 51 can increase the quantity of light reflected in the central region CA by the reflection structure formed by the first multilayer reflector 13 and the substrate 11. This allows the surface emitting laser 50 to further increase oscillation efficiency of the light in the central region CA that produces a main part of the emitted light.

For example, the convex portion 51 can be formed by depositing resist on the back surface of the substrate 11 in the same shape as the convex portion 51 and dry etching the entire back surface of the substrate 11 to transfer the shape of the resist to the back surface of the substrate 11.

In the above description, while the convex portion 51 is in a convex lens shape, the shape of the convex portion 51 may be another shape as long as the shape ensures collecting the light reflected by the reflection structure formed by the first multilayer reflector 13 and the substrate 11 in the central region CA. For example, the convex portion 51 may be in a parabolic shape projecting downward.

In FIG. 6, while the slit grooves 41 are formed only in the region opposed to the opening 25H, the slit grooves 41 may extend further outward without limiting only in the region opposed to the opening 25H.

In Embodiments 1 to 3 above, while the electrical contact surface 21S defined by the opening 25H is in an elliptical shape, the electrical contact surface 21S may have another shape as long as the shape has a longitudinal direction in the direction along the axis AX1. In other words, the central region CA may be a columnar portion, such as a prismatic column, having a bottom surface in another shape other than an ellipse as long as the shape has a longitudinal direction in the direction along the axis AX1.

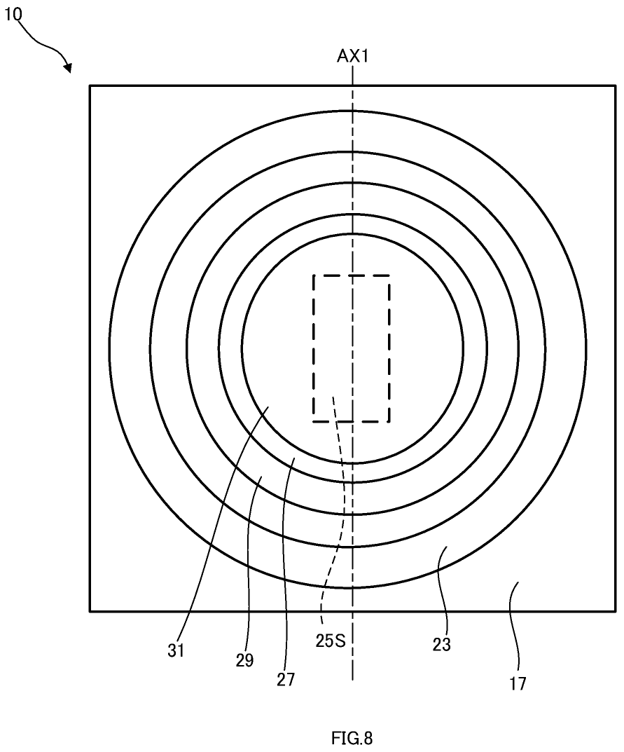

For example, as illustrated in FIG. 8, the electrical contact surface 21S may be in an oblong shape or rectangular shape having a longitudinal direction in the direction along the axis AX1. That is, the central region CA may be a columnar region with a bottom surface in an oblong shape having a longitudinal direction in the direction along the axis AX1.

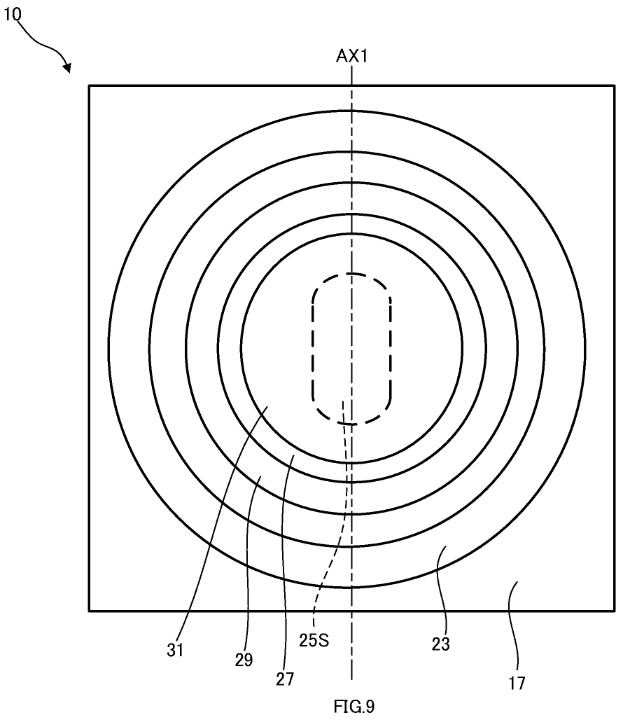

In addition, for example, as illustrated in FIG. 9, the electrical contact surface 21S may be an oval face having an outline identical to a running track having a longitudinal direction in the direction along the axis AX1 direction. That is, the central region CA may be a region overlapping with a columnar body, the bottom surface of which is in an oval shape having an outer shape identical to a running track shape having a longitudinal direction in the direction along the axis AX1.

Moreover, for example, the electrical contact surface 21S may be a rhombic face having a longitudinal direction in the direction along the axis AX1.

The electrical contact surface 21S may have a ring shape or frame shape, such as an elliptical ring shape, square frame shape, or running track shape.

In the above examples, for the polarization control in the surface emitting laser of the present invention, the case where the electrical contact surface 21S is in a two-fold symmetric shape having a longitudinal direction in the axis AX1, such as an ellipse, an oblong shape, and an oval having an outline identical to a running track shape has been described. However, the above polarization control in the surface emitting laser of the present invention can be realized even if the electrical contact surface 21S has a figure of 2n-fold symmetry (n>1), such as four-fold symmetry and six-fold symmetry.

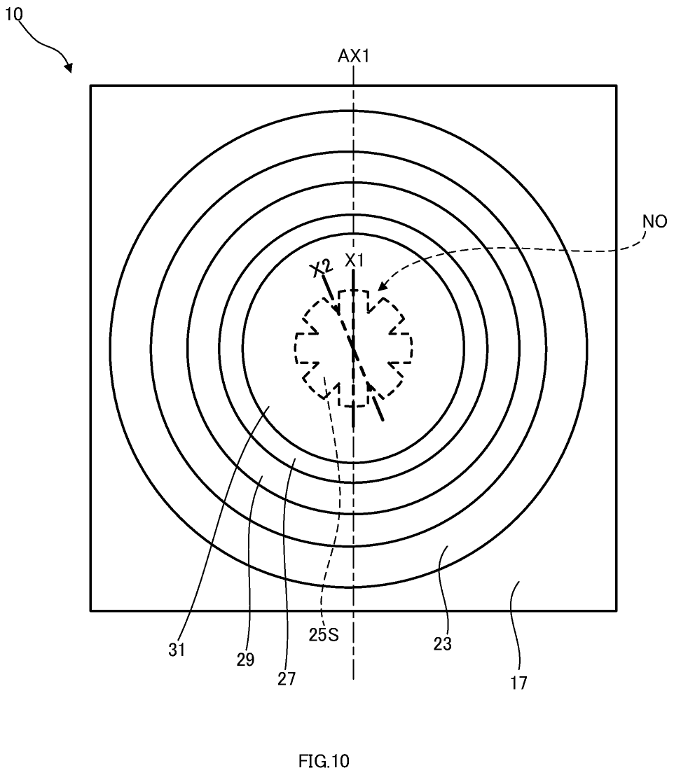

For example, as with a top view of a modification of the surface emitting laser 10 of Embodiment 1 illustrated in FIG. 10, the electrical contact surface 21S may have a figure of eight-fold symmetry. In such a case, when of line symmetry axes X1 and X2 (two-dot chain bold lines in the drawing) of the figure shaping the electrical contact surface 21S, the axis having the longest length overlapping with the figure, which is X1 in the case illustrated in FIG. 10, matches the axis AX1, the polarization control effect similar to that of the surface emitting lasers of Embodiments 1 to 3 described above can be obtained.

Note that the shape of the electrical contact surface 21S illustrated in FIG. 10 is a shape formed by forming notch portions NO in a circle. The notch portions NO extend in a radial direction from an outer edge of the circle toward the center. That is, the electrical contact surface 21S illustrated in FIG. 10 has segmented regions that are separated to some extent in a circumferential direction by these notch portions NO, in other words, sandwiched between the notch portions NO.

When a surface emitting laser having the electrical contact surface 21S as illustrated in FIG. 10 is driven, the standing wave is confined in respective regions corresponding to the above segmented regions in the resonator OC, and the position of the standing wave is fixed in a circumferential direction of the luminescence center axis AX2. This facilitates controlling light-emitting patterns of the surface emitting laser in the circumferential direction of the luminescence center axis AX2. For example, when the shape of the electrical contact surface 21S is a shape illustrated in FIG. 10, in a near-field pattern of light emitted from the light-emitting surface on the lower surface of the substrate 11, what is called emitted light, light-emitting patterns having intensity peaks at positions corresponding to the above segmented regions are confirmed. In a far-field pattern of the emitted light, a monomodal beam pattern having an intensity peak at a point on the luminescence center axis AX2 is confirmed.

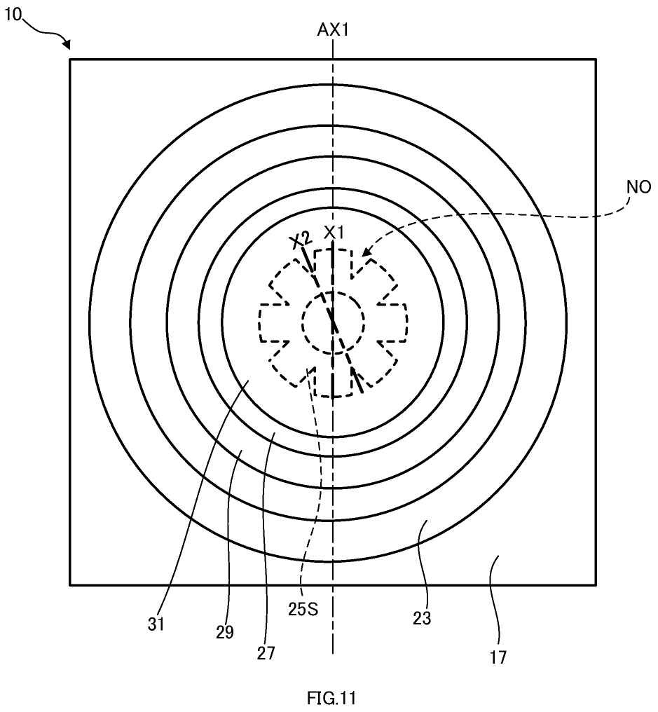

FIG. 11 illustrates a top view of the surface emitting laser 10 in which the shape of the electrical contact surface 21S is a shape formed by hollowing out the center of the shape of the electrical contact surface 21S illustrated in FIG. 10 in a circular shape. The shape portion hollowed out in a circular shape at the center is a non-conducting region that has no electrical contact between an electrode and the p-type semiconductor layer 21. That is, the electrical contact surface 21S illustrated in FIG. 11 has a shape formed by forming the notch portions NO in a circular ring. The notch portions NO extend in the radial direction from the outer edge of the circular ring toward the center.

In this case, the polarization control and the light-emitting pattern control similar to those of the surface emitting laser illustrated in FIG. 10 can be realized by matching the line symmetry axis X1 of the electrical contact surface 21S with the axis AX1.

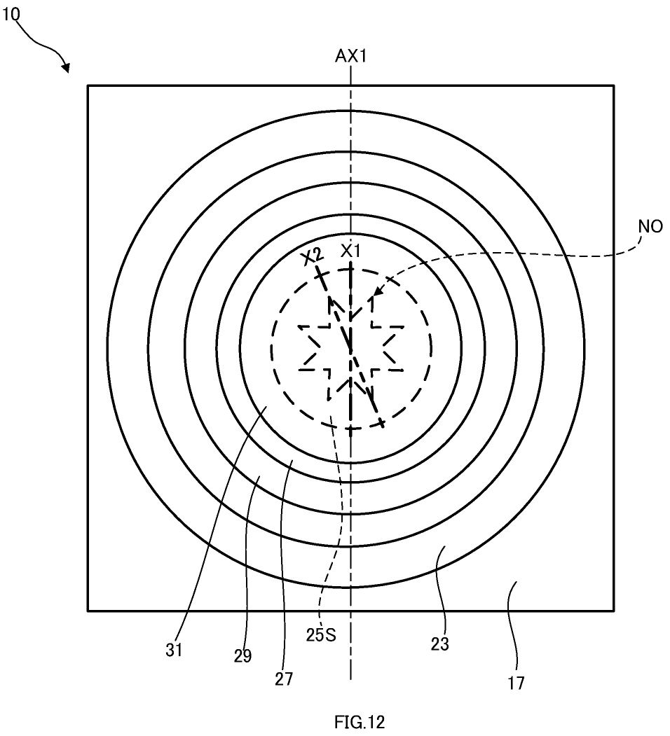

FIG. 12 illustrates a top view of the surface emitting laser 10 in which the shape of the electrical contact surface 21S is a shape formed by forming the notch portions NO in a circular ring. The notch portions NO extend in the radial direction from an inner edge of the circular ring to an outer side. A region at the center of the circular ring including the notch portions NO is a non-conducting region that has no electrical contact between an electrode and the p-type semiconductor layer 21. That is, the electrical contact surface 21S illustrated in FIG. 12 has segmented regions that are separated to some extent in the circumferential direction by these notch portions NO, in other words, sandwiched between the notch portions NO.

In this case, the polarization control and the light-emitting pattern control similar to those of the surface emitting laser illustrated in FIG. 10 can be realized by matching the line symmetry axis X1 of the electrical contact surface 21S with the axis AX1.

In the above-described embodiments, in order to form the electrical contact surface 21S on the upper surface of the p-type semiconductor layer 21 and an insulating region therearound to form a region where current confinement is generated and a refractive index is low, the insulating layer 25 is disposed. However, instead of disposing the insulating layer 25, another method may be used to create a region where current confinement is generated and a refractive index is low.

For example, by etching the upper surface of the p-type semiconductor layer 21 on which the insulating layer 25 is disposed in the above embodiments, an insulating region, a region with low refractive index, and the electrical contact surface 21S may be formed. In addition, by implanting ions on the upper surface of the p-type semiconductor layer 21 on which the insulating layer 25 is disposed, an insulating region, a region with low refractive index, and the electrical contact surface 21S may be formed to produce the same effects as the case where the insulating layer 25 is formed in the above embodiments. When the ion implantation is performed, for example, B ions, Al ions, or oxygen ions are implanted to the p-type semiconductor layer 21.

Moreover, in the surface emitting laser as described above, the semiconductor structure layer 15 may be formed by laminating a p-GaN layer, an active layer similar to that of the above embodiments, and an n-GaN layer on the n-type semiconductor layer 17 in this order. In this case, a tunnel junction layer made of an n⁺-GaN layer and p⁺-GaN may be formed in a portion overlapping with the central region CA of the above embodiments in the top view in a region of the p-GaN layer in contact with the n-type semiconductor layer 17.

In a semiconductor structure layer having this configuration, from the p-GaN layer to the n-type semiconductor layer 17, a current flows in only from the tunnel junction layer portion. Therefore, it is possible to produce the current confinement effect similar to that of the case where the insulating layer 25 is formed as described above. In other words, by forming the tunnel junction layer that forms a tunnel junction in the same region as the electrical contact surface 21S described above in the top view, it is possible to obtain the current confinement effect and the polarization control effect similar to those of the case where the electrical contact surface 21S is formed as described above.

In the above embodiments, while the case where the upper surface of the substrate 11 is a surface offset by 0.5° in the direction from the C-plane to the M-plane, that is, the case where the offset angle in the direction from the C-plane to the M-plane is 0.5° has been described, the offset angle is not limited to this angle. When the offset angle is, for example, from about 0.3° to 0.8°, the polarization control effect described above can be sufficiently obtained. When the offset angle of the upper surface of the substrate 11 is 0.8° or less, semiconductor multilayer films constituting the first multilayer reflector 13 can be formed to stably have sufficient reflectivity.

In the above embodiments, while a coreless substrate is used as the substrate 11, a stripe core substrate may be used. In this case, a direction of the stripe of cores of the substrate 11 is parallel or perpendicular to an inclined direction of a crystal plane of the upper surface of the substrate 11 in the top view of the substrate 11. That is, in the above embodiments, the m-axis direction of the substrate 11 is parallel or perpendicular to the direction of the stripe of the cores of the substrate 11.

In the above embodiments, while the case where the upper surface of the substrate 11 is offset in the direction of C-plane to M-plane has been described, the upper surface of the substrate 11 may be offset in the direction from the C-plane to the A-plane and hardly offset in the C-plane direction.

In this case, in order to obtain the above polarization control effect, for reasons similar to those described for the above range of the offset angle of the C-plane, the offset angle in the direction from the C-plane to the A-plane is preferably from about 0.3° to 0.8°, and the offset angle from the C-plane to the M-plane is preferably 0±0.1°. Note that, when the upper surface of the substrate 11 is offset from the C-plane to the A-plane, it should be read differently and understood that AX1 corresponds to an a-axis in the description regarding the shape of the electrical contact surface 21S in the above embodiments.

When the upper surface of the substrate 11 is offset in the direction from the C-plane to the A-plane, a large quantity of light having a polarization direction along an a-axis direction can be taken out, and the emission of the light having a polarization direction other than the direction along the a-axis can be reduced. Therefore, with the surface emitting laser 10, a variation in the polarization direction of the light taken out from the light-emitting surface in the in-plane direction of the light-emitting surface can be reduced.

Various values, dimensions, materials, and the like in Embodiments described above are merely examples, and can be appropriately selected corresponding to the usage and the fabricated surface emitting laser.

### DESCRIPTION OF REFERENCE SIGNS

10, 40, 50 . . . surface emitting laser
11 . . . substrate
13 . . . first multilayer reflector
15 . . . semiconductor structure layer
17 . . . n-type semiconductor layer
19 . . . active layer
21 . . . p-type semiconductor layer
23 . . . n-electrode
25 . . . insulating layer
27 . . . transparent electrode
29 . . . p-electrode
31 . . . second multilayer reflector

1. A vertical cavity light-emitting element comprising:
a gallium-nitride-based semiconductor substrate;
a first multilayer reflector made of a nitride semiconductor formed on the substrate;
a semiconductor structure layer including a first semiconductor layer, an active layer, and a second semiconductor layer, the first semiconductor layer being made of a nitride semiconductor having a first conductivity type formed on the first multilayer reflector, the active layer being made of a nitride semiconductor formed on the first semiconductor layer, the second semiconductor layer being formed on the active layer and made of a nitride semiconductor having a second conductivity type opposite to the first conductivity type;
a first electrode layer electrically in contact with the first semiconductor layer of the semiconductor structure layer;
a second electrode layer formed on an upper surface of the semiconductor structure layer, the second electrode layer being electrically in contact with the second semiconductor layer of the semiconductor structure layer in one region of the upper surface of the semiconductor structure layer; and
a second multilayer reflector formed on the second electrode layer to cover the one region, the second multilayer reflector configuring a resonator between the first multilayer reflector and the second multilayer reflector,
wherein:
an upper surface of the gallium-nitride-based semiconductor substrate is a surface offset from a c-plane to any one of crystal planes of an M-plane m-plane or an a-plane, and
the one region has:
a shape having a longitudinal direction in an m-axis direction when the upper surface of the gallium-nitride-based semiconductor substrate is offset to the m-plane, and
a shape having a longitudinal direction in an a-axis direction when the upper surface of the gallium-nitride-based semiconductor substrate is offset to the a-plane.

2. The vertical cavity light-emitting element according to claim 1, wherein:
a plurality of slit-shaped recessed portions parallel to one another are formed in a region on a lower surface of the gallium-nitride-based semiconductor substrate, the region on which the plurality of slit-shaped recessed portions are formed overlapping with the one region when viewed in a normal direction of the gallium-nitride-based semiconductor substrate, and
each of the slit-shaped recessed portions has:
a longitudinal direction in the m-axis direction when the upper surface of the gallium-nitride-based semiconductor substrate is offset to the m-plane, and
a longitudinal direction in the a-axis direction when the one upper surface of the gallium-nitride-based semiconductor substrate is offset to the a-plane.

3. The vertical cavity light-emitting element according to claim 1, wherein a region that is on a lower surface of the gallium-nitride-based semiconductor substrate and overlaps with the one region when viewed in a normal direction of the gallium-nitride-based semiconductor substrate has a convex lens shape projecting downward.

4. The vertical cavity light-emitting element according to claim 1, wherein the upper surface of the gallium-nitride-based semiconductor substrate is:
a surface offset by an angle of 0.8° or less from the c-plane to the m-plane when the upper surface is offset to the M plane m-plane, and
a surface offset by an angle of 0.8° or less from the c-plane to the a-plane when the upper surface is offset to the a-plane.

5. The vertical cavity light-emitting element according to claim 1, wherein;
the gallium-nitride-based semiconductor substrate is a stripe core substrate, and
a direction in which a core of the gallium-nitride-based semiconductor substrate extends is:
a direction along the m-axis when the upper surface is offset to the m-plane, and
a direction along the a-axis when the upper surface is offset to the a-plane.

6. The vertical cavity light-emitting element according to claim 1, wherein the one region is in has an oval shape.

7. The vertical cavity light-emitting element according to claim 1, wherein the one region is in has a rectangular shape.

8. A vertical cavity light-emitting element comprising:
a gallium-nitride-based semiconductor substrate;
a first multilayer reflector made of a nitride semiconductor formed on the substrate;
a semiconductor structure layer including a first semiconductor layer, an active layer, and a second semiconductor layer, the first semiconductor layer being made of a nitride semiconductor having a first conductivity type formed on the first multilayer reflector, the active layer being made of a nitride semiconductor formed on the first semiconductor layer, the second semiconductor layer being formed on the active layer and made of a nitride semiconductor having a second conductivity type opposite to the first conductivity type;
a first electrode layer electrically in contact with the first semiconductor layer of the semiconductor structure layer;
a second electrode layer formed on an upper surface of the semiconductor structure layer, the second electrode layer being electrically in contact with the second semiconductor layer of the semiconductor structure layer in one region of the upper surface; and
a second multilayer reflector formed to cover the one region on the second electrode layer, the second multilayer reflector configuring a resonator between the first multilayer reflector and the second multilayer reflector,
wherein:
an upper surface of the gallium-nitride-based semiconductor substrate is a surface offset from a c-plane to any one of crystal planes of an m-plane or an a-plane,
the one region is disposed so as to be in a shape of 2n-fold symmetry (n>1) having a first line symmetry axis and a second line symmetry axis, and
a direction of an axis having the longest length overlapping with the one region of the first line symmetry axis and the second line symmetry axis is:
an m-axis direction when the upper ene surface of the gallium-nitride-based semiconductor substrate is offset to the m-plane, and
an a-axis direction when the one upper surface of the gallium-nitride-based semiconductor substrate is offset to the a-plane.

9. The vertical cavity light-emitting element according to claim 8, wherein the one region is disposed to be in a shape surrounding a region in which the second electrode layer is not in electric contact with the second semiconductor layer.
